(19) United States
(12) Patent Application Publication
(10) Pub. No.: US 2025/0231474 A1
(43) Pub. Date: Jul. 17, 2025

(54) APPARATUSES AND METHODS FOR ASSESSING DEEP ULTRAVIOLET REFLECTIVITY OF A PELLICLE FOR AN EXTREME ULTRAVIOLET PHOTOLITHOGRAPHY MASK

(71) Applicant: Taiwan Semiconductor Manufacturing Company, LTD., Hsinchu (TW)

(72) Inventors: Kelvin Elphick, Hsinchu (TW); Hung Lin Chen, Taipei (TW); Yun-Yue Lin, Hsinchu (TW)

(21) Appl. No.: 18/414,622

(22) Filed: Jan. 17, 2024

(51) Int. Cl. G03F 1/62; G01N 21/956

(52) U.S. Cl. CPC G03F 1/62; G01N 21/956; G01N 2021/95676

(57) ABSTRACT

A two-dimensional deep ultraviolet (DUV) reflectivity map of an extreme ultraviolet (EUV) pellicle is acquired using a DUV reflectance measurement assembly having a DUV light source and a DUV spectrophotometer. A representation of the two-dimensional DUV reflectivity map may be displayed. Additionally or alternatively, it may be determined whether the EUV pellicle is usable for EUV lithography without a dynamic gas lock DUV light-reflective membrane by analyzing the two-dimensional DUV reflectivity map, and outputting an indication of the determination. In response to a determination that the EUV pellicle is usable, the EUV pellicle may be mounted on an EUV photolithography mask to form an EUV mask assembly and EUV photolithography performed using the EUV mask assembly to form a latent image of a pattern of EUV reflective and absorbing regions of the photomask on and/or in an EUV light-sensitive photoresist layer disposed on a surface of a semiconductor wafer.

### BACKGROUND

The following relates to the semiconductor device arts, integrated circuit (IC) arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates an extreme ultraviolet (EUV) photolithography system including an EUV light source and an EUV scanner, and further illustrates a method for assessing deep ultraviolet (DUV) reflectivity of an EUV pellicle used with an EUV photomask employed in the EUV scanner, in which the method utilizes a DUV mapping apparatus.

FIGS. 2 and 3 diagrammatically illustrate side and top views, respectively, of an EUV pellicle DUV mapping apparatus.

FIG. 4 diagrammatically illustrates a top view of an EUV pellicle DUV mapping apparatus according to another embodiment.

FIG. 5 diagrammatically illustrates a method of operating an EUV pellicle DUV mapping apparatus to assess an EUV pellicle.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An extreme ultraviolet (EUV) photolithography exposure tool (also referred to herein as an EUV scanner) may include a dynamic gas lock (DGL) positioned between the projection module and the photoresist-coated semiconductor wafer onto which a latent image is to be formed. The DGL provides gas flow (e.g., nitrogen or argon gas) at a rate and flow pattern designed to provide contamination control. In some designs, the DGL may include a DGL membrane that is interposed between the projection module and the semiconductor wafer. The DGL membrane filters out-of-band light from EUV light source. The out-of-band light is predominantly deep ultraviolet light (DUV) at wavelengths in the spectral range between 193 nm-238 nm. The EUV-sensitive photoresist is also partially sensitive to DUV spectrum; hence, the DGL membrane advantageously blocks this DUV light from reaching the photoresist.

However, the DGL membrane also reduces the EUV light throughput, reducing the EUV source intensity for the EUV lithographic exposures. In some examples, this results in approximately 10% throughput reduction. Removal of the DGL membrane would advantageously avoid this undesired EUV light absorption, but at the cost of undesired DUV light reaching the photoresist. A consequence of this is that the DUV light also interacts with the EUV-sensitive photoresist and can cause degradation of the latent image which is designed to be produced by the EUV light. The impact of the DUV light can, for example, take the smallest features of the latent image (sometimes referred to as the critical dimension) out of the design specification. This impact is sometimes most prevalent at corner areas of the latent image. The DUV-caused degradation of the latent image can in turn result in reduction of the yield of integrated circuits (ICs) fabricated using the EUV photolithography exposure.

Another approach for suppressing the undesired DUV light is to design an EUV pellicle disposed over the photolithography mask to provide high EUV transmittance as well as low DUV reflectivity. The EUV pellicle is principally used for protecting the surface of the photolithography mask from contamination by particulates or the like. The EUV pellicle is thus designed to have high EUV transmittance. By also designing the EUV pellicle to have low DUV reflectivity, the EUV pellicle can additionally serve to remove the undesired DUV light, thus potentially making the separate DUV-blocking DGL membrane unnecessary.

In some embodiments disclosed herein, a pellicle DUV reflectivity mapping method is disclosed for evaluating the usability of the EUV pellicle for the additional DUV light removal function. In some embodiments disclosed herein, a pellicle DUV reflectivity mapping apparatus is also disclosed. In yet other embodiments disclosed herein, a photolithography exposure method includes acquiring a two-dimensional DUV reflectivity map of an EUV pellicle (e.g., using the above-mentioned method and/or apparatus), determining DUV reflectivity of the EUV pellicle is less than a maximum DUV reflectivity threshold by analyzing the two-dimensional DUV reflectivity map, and, in response to the determination that the DUV reflectivity of the EUV pellicle is less than the maximum DUV reflectivity threshold using the EUV pellicle in an EUV photolithography exposure. This latter operation may entail, for example, mounting the EUV pellicle on an EUV photolithography mask to form an EUV mask assembly, and performing EUV photolithography using the EUV mask assembly to form a latent image of a pattern of EUV reflective and absorbing regions of the photomask on and/or in an EUV light-sensitive photoresist layer disposed on a surface of a semiconductor wafer.

In the following, some nonlimiting illustrative examples of such methods and apparatuses are described.

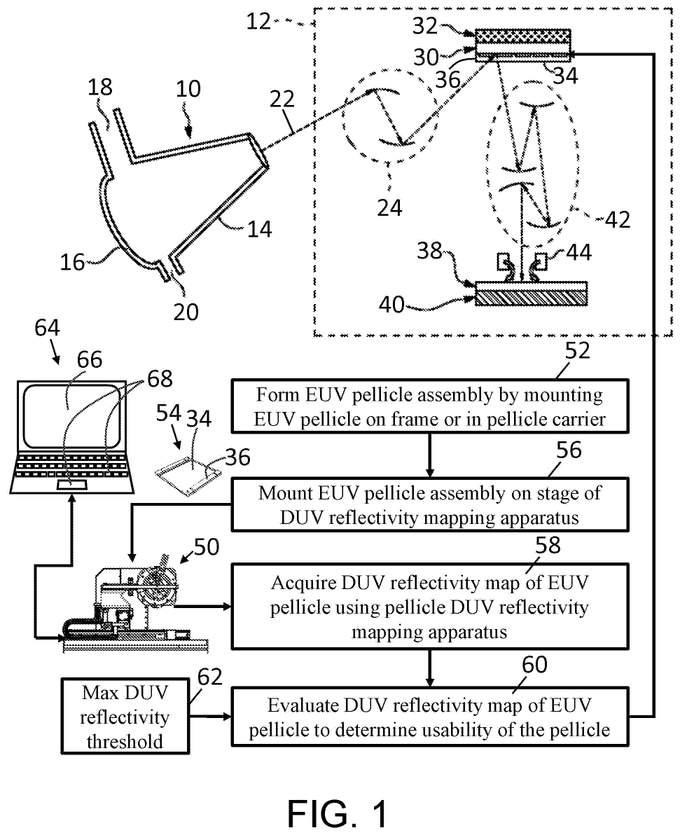

With reference to FIG. 1, an extreme ultraviolet (EUV) photolithography system includes an EUV light source 10 and an EUV scanner 12. The illustrative EUV light source 10 is a laser-produced plasma (LPP) EUV light source, such as a pulsed tin plasma EUV light source. In operation, the EUV light source 10 may be driven by a high power laser (not shown) such as a carbon dioxide (CO₂) laser or another pulsed laser that injects or shoots a pulsed laser beam into the vacuum (or other environmentally controlled) chamber 14, for example, via an optical window. In some embodiments, the laser beam is injected from under or behind an EUV light collector mirror 16 and passes through a small hole, aperture or opening arranged at or near a center of the collector mirror 16. In some embodiments, the EUV light collector mirror 16 is a multi-layer construction forming a reflective mirror at and/or about the operative wavelength of the EUV light source 10. A target droplet generator (not shown) is installed at a vacuum port 18 of the vacuum chamber 14, and injects droplets of a target material (for example, tin) into the vacuum chamber 14. The target droplet is propelled toward a droplet catcher (not shown) installed at a port 20 opposite the port 18. The optical pulses of the laser are timed to impinge on the target droplets (for example, at or near the ignition site) as they pass through a focus of the EUV light collector mirror 16 to produce a plasma which generates extreme ultraviolet EUV light. In the case of tin droplets, for example, the EUV light has a spectrum roughly spanning a 2% FWHM bandwidth in a range centered at about 13.5 nm. More generally, the generated EUV light may be centered at a chosen wavelength in an EUV range of between about 1 nm and about 100 nm. The collector mirror 16 reflects and focuses the plasma-generated EUV light to form EUV light 22 that exits the EUV light source 10 and passes into the EUV scanner 12. It is to be appreciated that the EUV light source 10 shown in FIG. 1 is a nonlimiting illustrative example, and that more generally any EUV light source that generates EUV light at a desired EUV wavelength can be utilized, such as by way of a further nonlimiting example an EUV light source employing a rotating annular crucible whose inside surface carries the tin or other target material.

As further shown in FIG. 1, the EUV scanner 12 comprises a vacuum chamber (shown as a dashed box in FIG. 1), and includes the illumination module 24 which is arranged to receive the EUV light. The illumination module 24 includes one or more optical elements (for example, EUV-reflective mirrors) that direct the EUV light 22 onto an EUV photolithography mask 30 (also referred to herein and in the art as a mask or photomask or reticle or the like). The photomask 30 is mounted on a photomask holder 32, such as an electrostatic chuck. The photomask 30 has a pattern of EUV-reflective and EUV-absorbing regions, forming an image that is to be transferred to a photoresist layer on a semiconductor wafer 38 that is disposed in the EUV scanner on a wafer holder 40, which may for example comprise an electrostatic chuck for holding the wafer 38. The sensitive patterned surface of the photomask 30 is suitably protected by a pellicle 34 that is mounted on the front of the photomask 30 by a frame 36 that spaces the pellicle 34 away from the front of the photomask 30 by a defined distance.

The pellicle 34 is an EUV pellicle 34 comprising an EUV light-transmissive membrane that prevents particles from depositing on the front surface of the photomask 30. The EUV pellicle is thin to enable it to transmit EUV light. For example, in some nonlimiting illustrative embodiments the EUV pellicle 34 may have a thickness of 10-100 nanometers, although greater or lesser thicknesses are contemplated. The EUV pellicle 34 may be made of various materials, such as by way of nonlimiting illustrative example graphene, carbon nanotubes, or so forth. The pellicle 34 is relatively fragile, due to its thinness. The pellicle frame 36 supports the fragile pellicle 34 over the surface of the photomask 30 at a separation distance sufficient to take the pellicle 34 outside the focal plane of the light from the illumination module 24 impinging on the photomask 30 during the lithography process. For example, the pellicle frame 36 may have a thickness of several millimeters (mm) to position the pellicle 34 over the surface of the photomask 30, in some nonlimiting illustrative embodiments. The pellicle frame 36 can be made from suitable materials such as anodized aluminum, stainless steel, plastic, silicon (Si), titanium, silicon dioxide, aluminum oxide (Al₂O₃), or titanium dioxide (TiO₂). The pellicle frame 36 is a rectangular or other encircling frame that coincides with and supports the full perimeter of the pellicle 34.

A projection module 42 of the EUV scanner 12 projects the EUV reflected from the EUV mask 30 onto a semiconductor wafer 38, and more particularly onto an EUV light-sensitive photoresist layer disposed on (e.g., coating) a surface of the semiconductor wafer 38. The projection module 42 includes a plurality of EUV-reflective mirrors arranged to project an image of the photomask 30 onto the photoresist coating the semiconductor wafer 38 to form a latent image of the pattern of EUV reflective and absorbing regions of the photomask 30 on and/or in the EUV light-sensitive photoresist. This constitutes an EUV photolithography exposure. In some embodiments, the EUV scanner 12 is configured to perform step-and-shoot EUV photolithography exposures to form a two-dimensional array of latent images of the photomask 30 on and/or in the photoresist coating the semiconductor wafer 38. For example, each latent image may correspond to a single integrated circuit (IC) die being fabricated on the semiconductor wafer 38.

After the EUV photolithography exposure (or exposures) is complete, the semiconductor wafer 38 is removed from the EUV scanner 12, and a suitable developer is applied to develop the latent image by etching away those portions of the photoresist that were exposed to the EUV light (this is the case for a positive EUV photoresist); or conversely by etching away those portions of the photoresist that were not exposed to the EUV light (this is the case for a negative EUV photoresist). The developing produces a pattern of openings in the developed photoresist, through which subsequent semiconductor processing steps such as etching, deposition, or the like are performed to form semiconductor device structures or the like in photolithographically controlled areas.

The foregoing process ideally operates with only EUV light produced by the EUV light source 10. However, in practice, the EUV light source 10 also generates some unwanted deep ultraviolet (DUV) light, e.g., in a DUV wavelength range of about 190 nm to about 250 nm. The DUV light can also interact with the EUV-sensitive photoresist coating the semiconductor wafer 38. Put another way, the EUV-sensitive photoresist also has some DUV light sensitivity. DUV light interaction with the EUV-sensitive photoresist can degrade the fidelity between the latent image and the pattern of EUV reflective and absorbing regions of the photomask 30, ultimately leading to defects in semiconductor devices having fabrication regions defined by the developed photoresist layer.

As previously mentioned, one way to address the problem of stray DUV light reaching the photoresist coating the semiconductor wafer 38 is to provide a dynamic gas lock (DGL) 44 with a DUV light-reflective membrane. The DGL 44 is positioned in the optical path before the wafer 38 disposed on the wafer holder 40, and provides gas flow (e.g., nitrogen or argon gas) at a rate and flow pattern designed to provide contamination control. The DGL 44 may include a DUV-reflective membrane that forms an optical filter tuned to block DUV light from reaching the photoresist coating the semiconductor wafer 38. The DUV-reflective membrane of the DGL 44 is a consumable element with a useful lifetime of a few months or so, and replacing the DGL membrane entails shutting down operation of the EUV scanner 12. As previously discussed, the DGL membrane also has the side effect of absorbing some EUV light, and in some cases this resulting in about a 10% EUV light intensity decrease.

In some embodiments disclosed herein, the EUV pellicle 34 comprising an EUV light-transmissive membrane that also has high reflectivity for DUV light. In this way, the EUV pellicle provides the desirable function of reducing or eliminating the amount of stray DUV light reaching the semiconductor wafer 38. In some such embodiments, the DGL membrane may be omitted, since its DUV light-blocking function is instead provided by the EUV pellicle with low DUV reflectivity.

However, this approach would benefit from providing a way to ensure the EUV pellicle is in fact sufficiently DUV reflective to provide the desired reduction in DUV light reaching the semiconductor wafer 38. Such evaluation of the EUV pellicle is challenging. As previously noted, the EUV pellicle 34 is very thin to enable sufficient EUV light transmissivity, e.g. the EUV pellicle 34 may have a thickness of 10-100 nanometers, although greater or lesser thicknesses are contemplated. The EUV pellicle 34 may also have a large two-dimensional area, and this area may vary widely between different EUV pellicles. As two nonlimiting illustrative examples, an EUV pellicle used for research may have a relatively small area of about 1 cm×1 cm, while one EUV pellicle 34 for commercial semiconductor fabrication facility use has a much larger area of 143 mm×110 mm. Even larger-area EUV pellicles are contemplated to provide finer feature definition. The combination of thinness and relatively large area makes EUV pellicles relatively fragile components. Furthermore, the DUV reflectivity can vary over the (possibly relatively large) two-dimensional area of the EUV pellicle. DUV reflectivity can also vary as a function of wavelength across the DUV spectrum. Still further, different EUV pellicles may be designed to operate at different angles-of-incidence of the incident EUV light.

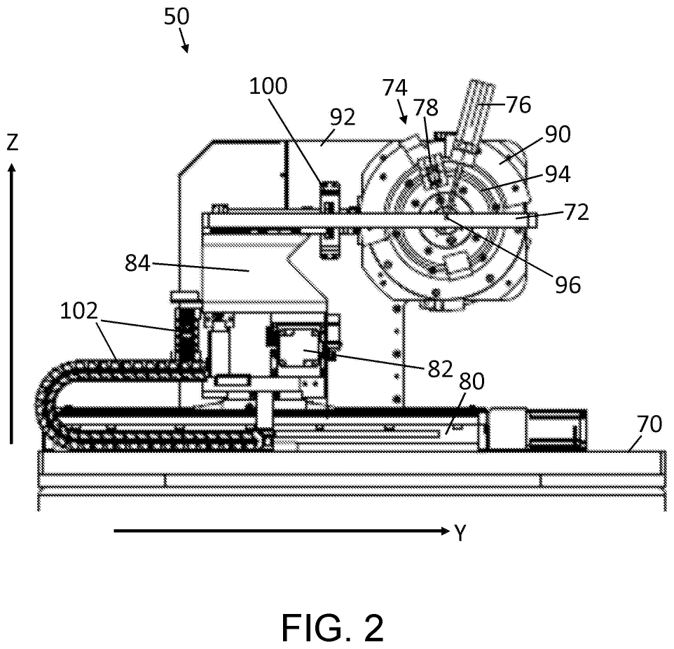

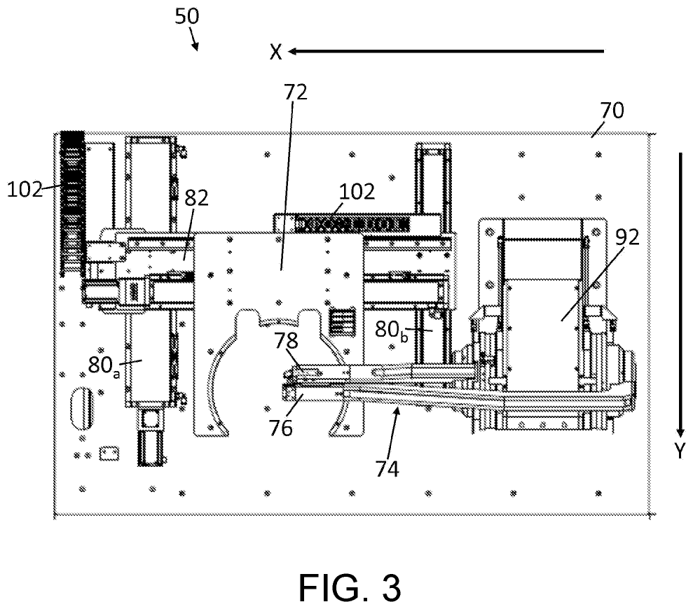

With reference to FIG. 1, an illustrative pellicle DUV reflectivity mapping apparatus 50 (shown in greater detail in FIGS. 2 and 3 to be described later) provides the ability to map fragile EUV pellicles of a wide range of sizes, yielding a two-dimensional DUV reflectivity map (i.e., image) of the EUV pellicle 34. Each data point in the two-dimensional DUV reflectivity map is a vector (or other suitable data structure) of reflectivity values as a function of wavelength. Some embodiments of the pellicle DUV reflectivity mapping apparatus 50 may also provide for measuring the two-dimensional DUV reflectivity map at a user-selectable angle of incidence, or at multiple angles of incidence (e.g., a two-dimensional DUV reflectivity map acquired for each angle of incidence that is measured).

With continuing reference to FIG. 1, a photolithography exposure method is shown which uses the pellicle DUV reflectivity mapping apparatus 50 to verify usability of the EUV pellicle 34. In an operation 52, an EUV pellicle assembly 54 is formed, which in the illustrative example includes the EUV pellicle 34 mounted on the frame 36. In this case, the frame 36 is the same frame that is used to mount the EUV pellicle 34 on the photomask 30 with the pellicle 34 spaced away from the front of the photomask 30 by a defined distance. The frame 36 provides structural support for the thin EUV pellicle 34. In other embodiments, the pellicle assembly 54 may comprise the EUV pellicle 34 mounted on a pellicle carrier (not shown) of a type used for transport and storage of an EUV pellicle. Again, the pellicle carrier provides structural support for the EUV pellicle 34 in this alternative embodiment of the EUV pellicle assembly 54.

In an operation 56, the EUV pellicle assembly 54 is mounted on a stage of the pellicle DUV reflectivity mapping apparatus 50. In an operation 58, the pellicle DUV reflectivity mapping apparatus 50 is operated to acquire a DUV reflectivity map of the EUV pellicle 34. As will be further discussed later, this entails two-dimensionally scanning DUV light from a DUV light source across the surface of the EUV pellicle 34 and measuring the DUV light reflected from the EUV pellicle 34 as a function of wavelength using a spectrophotometer.

In an operation 60, the DUV reflectivity map of the EUV pellicle 34 is evaluated (i.e., analyzed) to determine usability of the EUV pellicle 34 for EUV photolithography exposures. In some examples, the determined usability of the EUV pellicle 34 is whether the EUV pellicle 34 is usable for EUV photolithography exposures without a DUV light-blocking DGL membrane being mounted in the DGL 44. In some embodiments, the operation 60 determines whether the EUV pellicle 34 is usable by determining whether the DUV reflectivity of the EUV pellicle 34 is less than a maximum DUV reflectivity threshold 62 by analysis of the two-dimensional DUV reflectivity map.

In some nonlimiting illustrative embodiments of the operation 60, a reflectivity metric derived from the two-dimensional DUV reflectivity map is a maximum DUV reflectivity at a location on the two-dimensional DUV reflectivity map. In other words, the derived reflectivity metric is the highest DUV reflectivity at any location in the two-dimensional scan. To determine the DUV reflectivity at a given location, the DUV reflectivity may be summed over the wavelengths scanned by the spectrophotometer at that location. In this case, the maximum DUV reflectivity threshold 62 is the maximum permissible DUV reflectivity at any location on the EUV pellicle for the pellicle to be deemed usable.

In some other nonlimiting illustrative embodiments of the operation 60, a reflectivity metric derived from the two-dimensional DUV reflectivity map is a total DUV reflectivity integrated over the two-dimensional surface of the EUV pellicle. This integration is suitably over all locations of the two-dimensional scan and over all wavelengths scanned by the spectrophotometer. In this case, the maximum DUV reflectivity threshold 62 is the maximum total DUV reflectivity of the EUV pellicle for the pellicle to be deemed usable.

In yet other nonlimiting illustrative embodiments of the operation 60, both the above analyses may be performed, so that the EUV pellicle 34 is deemed usable only if it satisfies both the maximum DUV reflectivity criterion on a per-location basis and the maximum total DUV reflectivity criterion.

In response to a determination at the operation 60 that the DUV reflectivity of the EUV pellicle 34 is less than the maximum DUV reflectivity threshold 62, the EUV pellicle 34 may be mounted on an EUV photolithography mask 30 to form an EUV mask assembly (e.g., mounted in the EUV scanner 12 as shown in FIG. 1), and EUV photolithography performed (e.g., by the EUV scanner 12) using the EUV mask assembly to form a latent image of a pattern of EUV reflective and absorbing regions of the photomask 30 on and/or in an EUV light-sensitive photoresist layer disposed on a surface of a semiconductor wafer 38. If the EUV pellicle assembly 54 comprises the EUV pellicle 34 mounted on the frame 36, then this EUV pellicle assembly 54 can be mounted onto the EUV mask 30 to form the EUV mask assembly. Alternatively, if the EUV pellicle assembly 54 comprises the EUV pellicle 34 held by a pellicle carrier then the EUV pellicle 34 is transferred from the pellicle carrier to a mount 36 for mounting on the EUV photolithography mask 30. If the usability determination was usability without a DGL membrane, then the EUV photolithography performed using the EUV mask assembly to form the latent image may be performed without use of a DGL membrane. It is also noted that the EUV photolithography performed using the EUV mask assembly may form many latent images, e.g. a two-dimensional array of latent images using a step-and-scan process performed by the EUV scanner 12.

As previously described, the operation 60 determines usability of the EUV pellicle 34 for EUV photolithography exposures. Additionally or alternatively, the DUV reflectivity map of the EUV pellicle 34 may be evaluated to identify any DUV reflectivity “hot spots”, that is, regions of the EUV pellicle 34 that have elevated DUV reflectivity. For example, a DUV reflectivity hot spot may correspond to any region of the DUV reflectivity map where the local DUV reflectivity exceeds the maximum DUV reflectivity threshold 62. Identifying such a DUV reflectivity hot spot of the EUV pellicle 34 may be beneficial, for example, to assist in retrospective analysis of the manufacturing process used to manufacture the EUV pellicle 34 to determine to root cause in the manufacturing process of the DUV reflectivity hot spot.

Control of the pellicle DUV reflectivity mapping apparatus 50, and/or performance of the operations 58 and 60 making up the EUV pellicle usability test, may suitably be controlled by a controller 64 such as an illustrative computer 64 or other electronic processing device. The illustrative controller 64 includes a display 66 for displaying a rendering of the DUV reflectivity map of the pellicle 34, and/or for displaying an indication of the determination (from operation 60) of whether the EUV pellicle 34 is usable for EUV lithography without a dynamic gas lock DUV light-reflective membrane, and/or for displaying other information. The illustrative controller 64 optionally includes an illustrative keyboard, touchpad, and/or other user input device(s) 68 via which a user can enter or select configuration settings for the pellicle DUV reflectivity mapping apparatus 50 such as the DUV wavelength range the spectrophotometer scans, the angle of incidence, and/or so forth, and/or inputs or selects other information such as a value for the maximum DUV reflectivity threshold 62.

The representation of the DUV reflectivity map of the pellicle 34 optionally displayed on the display 66 can employ various rendering approaches. For example, the measured DUV reflectivity values at the locations on the EUV pellicle 34 can be color coded to produce the representation as a heat map, e.g. with a “hot” color such as red representing highest DUV reflectivity values and a “cool” color such as blue representing lowest DUV reflectivity values, and intermediate colors (green, yellow, orange, et cetera) representing intermediate reflectivity values. This is merely one nonlimiting illustrative example of a suitable representation.

The EUV pellicle usability test comprising the operations 58 and 60 may be performed at various times. In one use case, the EUV pellicle usability test 58, 60 may be performed on a newly acquired EUV pellicle, to determine its usability before it is first put into commercial use for performing EUV photolithography exposures. In another use case, the EUV pellicle usability test 58, 60 may be performed as part of a physical failure analysis (PFA) process. In this use case, if the semiconductor fabrication facility finds an IC fabrication workflow is producing an undesirably low yield it may be suspected that this may be due to stray DUV light degrading the latent images produced by the EUV lithography step(s) performed using the EUV scanner 12. In such a case, the EUV pellicle usability test 58, 60 may be applied to determine whether excessive DUV reflectivity from the EUV pellicle 34 is the cause of the observed low yield. In yet another use case, in research and development of EUV pellicles the EUV pellicle usability test 58, 60 may be applied to EUV pellicles fabricated as part of the research to determine whether the EUV pellicle has suitably low DUV reflectivity. These are merely some nonlimiting illustrative examples of use cases for the EUV pellicle usability test.

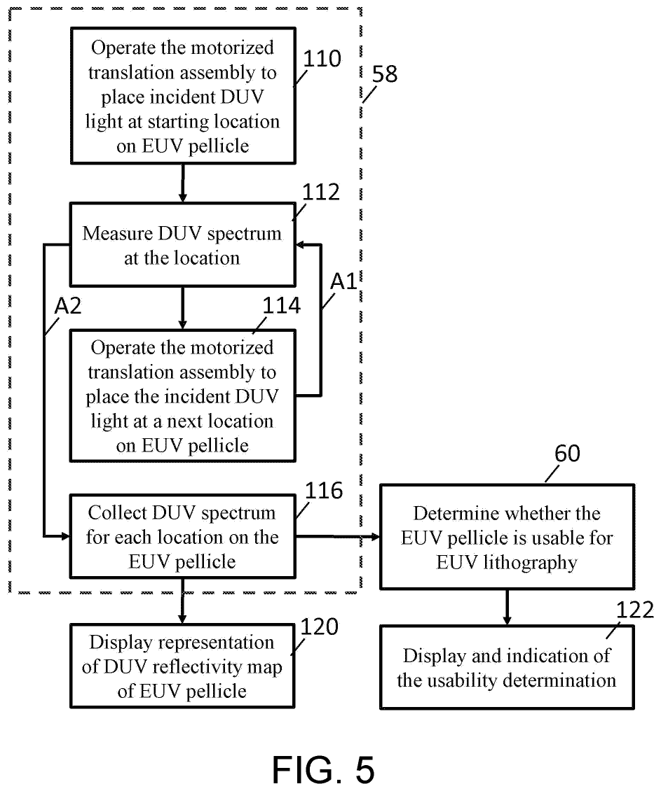

Moreover, it will be appreciated that the pellicle DUV reflectivity mapping apparatus 50 may be used to perform the pellicle DUV reflectivity mapping method 50 (an example of which is described later herein with reference to FIG. 5) without following this with the evaluation operation 60. For example, in a pellicle fabrication research and development context, the DUV reflectivity map of a pellicle fabricated during the research may be analyzed as a function of wavelength and/or angle of incidence to determine the underlying mechanisms controlling the DUV reflectivity to guide the research to obtain lower levels of DUV reflectivity in subsequently fabricated EUV pellicles.

With reference now to FIGS. 2 and 3, the illustrative pellicle DUV reflectivity mapping apparatus 50 is shown by way of a side view (FIG. 2) and a top view (FIG. 3). The illustrative pellicle DUV reflectivity mapping apparatus 50 of FIGS. 2 and 3 includes a base 70, a pellicle stage 72 configured to support an EUV pellicle (e.g., mounted on a frame 36 or in a pellicle carrier), and a DUV reflectance measurement assembly 74 including (i) a DUV light source 76 arranged to emit DUV light onto the EUV pellicle supported by the pellicle stage 72 to generate reflected DUV light that is reflected by the EUV pellicle, and (ii) a DUV spectrophotometer 78 arranged to measure intensity of the reflected DUV light as a function of wavelength or photon energy. A motorized assembly 80, 82 is secured to the base 70 and is configured to scan the DUV light (emitted by the DUV light source 76 onto the pellicle) over the EUV pellicle in two mutually orthogonal directions (designated direction X and direction Y in FIGS. 2 and 3) by translating the pellicle stage 72 and/or the DUV reflectance measurement assembly 74 respective to the base 70.

The DUV light source 76 can be any type of light source that emits light over the deep ultraviolet (DUV) spectrum over which DUV reflectivity of the EUV pellicle is to be measured (e.g., over at least 190 nm to 250 nm in some embodiments, as this constitutes a DUV range emitted by some embodiments of the EUV light source 10 and to which the EUV-sensitive photoresist is also sensitive). In some nonlimiting illustrative embodiments, the DUV light source 76 comprises a photomultiplier tube, and generation of the DUV light comprises operating the photomultiplier tube of the DUV light source 76 to emit the DUV light onto the EUV pellicle. The DUV light source 76 may also optionally include one or more optical components such as a lens and/or reflector operative over the DUV light range. These are merely some nonlimiting illustrative embodiments, and more generally the DUV light source 76 can be any DUV light source emitting in the desired spectral range.

The DUV spectrophotometer 78 suitably includes an optical detector that is sensitive over the DUV range for which DUV reflectivity of the EUV pellicle is to be measured, optically coupled with a grating or other spectral dispersion element that can be electronically adjusted (e.g., tilted in the case of a grating) to select a narrow DUV wavelength window (e.g., 1 nm window width in some nonlimiting illustrative embodiments) that is detected by the optical detector. The optical detector can be, for example, a silicon photodiode, avalanche photodiode (APD), CMOS sensor, or other silicon-based photosensor. The DUV spectrophotometer 78 optionally may include a quartz, sapphire, or other window, or may omit such a window to maximize DUV sensitivity at low DUV wavelengths. These are merely some nonlimiting illustrative embodiments, and more generally the DUV spectrophotometer 78 can be any DUV spectrophotometer providing sensitivity over the desired spectral range and with the desired spectral resolution.

In the illustrative embodiment of FIG. 1, the motorized assembly 80, 82 includes: a first mechanism 80 that is secured to the base 70 and is configured to move the pellicle stage 72 respective to the base in a first direction (without loss of generality labeled as the Y-direction in FIGS. 2 and 3); and a second mechanism 82 that is secured to the first mechanism 80 and is configured to move the pellicle stage 72 respective to the base 70 in a second direction (without loss of generality labeled as the X-direction in FIGS. 2 and 3) that is orthogonal to the first (e.g., Y) direction.

In the side view of FIG. 2 a third direction labeled the Z-direction is shown, where the X-direction, Y-direction, and Z-direction are suitably mutually orthogonal and form a conventional Cartesian coordinate system. The EUV pellicle being measured is suitably mounted on the pellicle stage 72 with the plane of the EUV pellicle oriented transverse to the Z-direction. Put another way, the surface normal of the EUV pellicle supported by the pellicle stage 72 is a unit vector oriented coincident or parallel with the Z-direction.

In the illustrative example of FIGS. 2 and 3, a pellicle stage supporter 84 (see FIG. 2) provides the structure connection between the pellicle stage 72 and the second linear translation mechanism 82. As seen in FIG. 3, the first linear translation mechanism 80 is, in the embodiment of FIGS. 2 and 3, made up of a first linear track 80a extending along the Y-direction and a second linear track 80b extending along the Y-direction; with the first and second linear tracks 80a and 80b located at or near opposite ends of the second linear translation mechanism 82. A suitable motor drive of the first linear translation mechanism 80, such as a motorized screw drive or a stepper motor, is operative to move the second linear translation mechanism 82 along the Y-direction. The second linear translation mechanism 82 comprises a linear track oriented along the X-direction, and a suitable motor drive of the second linear translation mechanism 82, such as a motorized screw drive or a stepper motor, is operative to move the pellicle stage 72 along the X-direction. Put another way, the second linear translation mechanism 82 directly supports the pellicle stage 72 and directly moves (i.e., linearly translates) the pellicle stage 72 along the X-direction. The first linear translation mechanism 80 directly supports the second linear translation mechanism 82 (and hence indirectly supports the pellicle stage 72) and directly moves the first linear translation mechanism 80 along the Y-direction (and hence indirectly moves the pellicle stage 72 along the Y-direction).

Thus, in the pellicle DUV reflectivity mapping apparatus 50 of FIGS. 2 and 3, the two-dimensional DUV reflectivity map of the EUV pellicle is acquired by scanning the EUV light emitted onto the EUV pellicle over a two-dimensional surface of the EUV pellicle using a combination of: moving the EUV pellicle (supported by the pellicle stage 72) in a first direction (e.g., Y-direction) respective to the DUV reflectance measurement assembly 74; and moving the EUV pellicle in a second direction (e.g., X-direction) respective to the DUV reflectance measurement assembly 74. The first direction and the second direction are mutually orthogonal.

In the embodiment of FIGS. 2 and 3, the DUV reflectance measurement assembly 74 is secured to the base 70 as does not move respective to the base 70; and the motorized assembly 80, 82 of FIGS. 2 and 3 is configured to translate the pellicle stage 72 respective to the base 70 and respective to the stationary DUV reflectance measurement assembly 74 that is secured to the base 70. However, other configurations of the motorized assembly are contemplated.

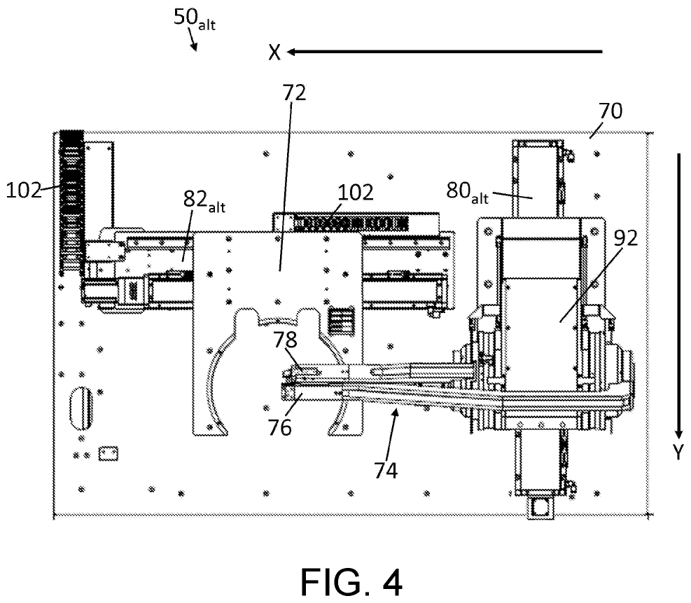

To provide a further nonlimiting illustrative example, FIG. 4 shows a top view of an alternative illustrative pellicle DUV reflectivity mapping apparatus 50ₐₗₜ, which is identical with the DUV reflectivity mapping apparatus 50 of FIGS. 2 and 3 except that the DUV reflectivity mapping apparatus 50ₐₗₜ employs a different motorized assembly 80ₐₗₜ, 82ₐₗₜ which is again secured to the base 70 and is configured to scan the DUV light (emitted by the DUV light source 76 onto the pellicle) over the EUV pellicle in two mutually orthogonal (e.g., X- and Y-) directions by translating the pellicle stage 72 and/or the DUV reflectance measurement assembly 74 respective to the base 70. The motorized assembly 80ₐₗₜ, 82ₐₗₜ of the alternative pellicle DUV reflectivity mapping apparatus 50ₐₗₜ includes: a first linear translation mechanism 80ₐₗₜ secured to the base 70 and configured to translate the DUV reflectance measurement assembly 74 respective to the base 70 in a first direction (e.g., the Y-direction in the embodiment of FIG. 4); and a second linear translation mechanism 82ₐₗₜ secured to the base 70 and configured to translate the pellicle stage 72 respective to the base 70 in a second direction (e.g., the X-direction in the embodiment of FIG. 4) that is orthogonal to the first direction.

In the alternative pellicle DUV reflectivity mapping apparatus 50ₐₗₜ of FIG. 4, the first and second linear translation mechanisms 80ₐₗₜ and 82ₐₗₜ suitably comprise respective first and second linear tracks oriented along the Y- and X-directions, respectively. Each of the first and second linear translation mechanisms 80ₐₗₜ and 82ₐₗₜ suitably include a motorized drive such as a motorized screw drive or a stepper motor operative to move the DUV reflectance measurement assembly 74 and the pellicle stage 72, respectively. The base 70 serves as the frame of reference for these movements.

Thus, in the alternative pellicle DUV reflectivity mapping apparatus 50ₐₗₜ of FIG. 4, the two-dimensional DUV reflectivity map of the EUV pellicle is acquired by scanning the EUV light emitted onto the EUV pellicle over a two-dimensional surface of the EUV pellicle using a combination of: moving the DUV reflectance measurement assembly 74 respective to the EUV pellicle (supported by the pellicle stage 72) in a first direction (e.g., Y-direction); and moving the EUV pellicle (by way of moving the pellicle stage 72) in a second direction (e.g., X-direction) respective to the DUV reflectance measurement assembly 74.

Again, these are merely nonlimiting illustrative examples. In yet another contemplated nonlimiting illustrative embodiment (not shown), it is contemplated for the pellicle stage to be stationary respective to the base, and for the motorized assembly secured to the base to be configured to scan the DUV reflectance measurement assembly in both X- and Y-directions respective to the base.

The DUV reflectivity of an EUV pellicle can depend on the angle of incidence of the DUV light on the EUV pellicle. Accordingly, as best seen in the side view of FIG. 2, the pellicle DUV reflectivity mapping apparatus 50 or 50ₐₗₜ optionally further includes a rotation motor 90 configured to adjust an angle of incidence of the DUV light emitted by the DUV light source 76 onto the EUV pellicle supported by the pellicle stage 72. A rotation unit cabinet 92 best seen in the top view of FIG. 3 or FIG. 4 provides a housing and support for the rotation motor 90. As best seen in the side view of FIG. 2, the rotation motor moves the DUV light source 76 and the DUV spectrophotometer 78 along a circular track 94 centered on an incidence location 96 of the DUV light onto the EUV pellicle supported by the pellicle stage 72. In general, the angle-of-reflection of the DUV light reflected into the spectrophotometer 78 equals the angle-of-incidence of the DUV light applied by the DUV light source 76 (where these angles are suitably measured respective to a surface normal of the EUV pellicle); hence, adjusting the angle-of-incidence of the DUV light source 76 entails commensurately adjusting the position of the spectrophotometer 78.

With general reference to FIGS. 2-4, the pellicle DUV reflectivity mapping apparatus 50 or 50ₐₗₜ may include additional components, such as one or more limit detectors 100 to detect if a translating moving component (e.g., the pellicle stage 72 in the embodiment of FIGS. 2 and 3) moves to a maximum (or minimum) permissible position, one or more electrical cables 102 for delivering power to the various motors, driving the DUV light source 76 and collecting DUV reflectivity data collected by the spectrophotometer 78. Electrical cables 102 that connect with a moving component (e.g., the second linear translation mechanism 82 in the example of FIGS. 2 and 3) are designed to accommodate the motion of the translating component, for example being constructed with a wire tracker or the like.

With continuing reference to FIGS. 2-4 and further reference back to FIG. 1, in some embodiments some or all the electrical cables 102 connect the pellicle DUV reflectivity mapping apparatus 50 (or 50ₐₗₜ) with the illustrative computer or other controller 64 which controls the pellicle DUV reflectivity mapping apparatus 50 (or 50ₐₗₜ) to acquire the DUV reflectivity map. The pellicle DUV reflectivity mapping apparatus 50 (or 50ₐₗₜ) is suitably used to perform the operation 58 of the photolithography exposure method. In the operation 58, the pellicle DUV reflectivity mapping apparatus 50 (or 50ₐₗₜ) is operated (e.g., by the controller 64) to acquire a DUV reflectivity map of the EUV pellicle 34.

With reference now to FIG. 5, a method is shown, by way of flowchart, of operating an EUV pellicle DUV mapping apparatus 50 (or 50ₐₗₜ) to assess an EUV pellicle. The method of FIG. 5 includes the pellicle DUV reflectivity mapping operation 58, a nonlimiting illustrative of which is shown in FIG. 5 by way of illustrative operations 110, 112, 114, and 116. In an operation 110, the motorized assembly 80, 82 (or 80ₐₗₜ, 82ₐₗₜ) is operated to place the incident DUV light from the DUV light source 76 at a starting location on the EUV pellicle supported by the pellicle stage 72.

In an operation 112, the DUV spectrum for the location is measured over a desired spectral range. In one nonlimiting illustrative example, the spectral range over which the DUV spectrum is measured is 190 nm to 500 nm, e.g., in 1 nm steps in one nonlimiting illustrative example. In another nonlimiting illustrative example, the spectral range over which the DUV spectrum is measured is at least 190 nm to 250 nm which is commensurate with the DUV wavelength range of about 190 nm to about 250 nm over which the EUV light source 10 (see FIG. 1) may in some embodiments generate unwanted DUV light. In some such embodiments, the DUV spectrum is measured over at least 190 nm to 250 nm in 1 nm steps, although smaller or larger steps are also contemplated. To acquire the DUV spectrum in the operation 112, a grating or other spectral dispersion element of the spectrophotometer 78 is used to sweep a spectral window (e.g., of about 1 nm in one nonlimiting illustrative example) of light entering a DUV light detector of the spectrophotometer 78 through the desired spectral range (e.g., 190-250 nm, or 190-500 nm, in two nonlimiting illustrative examples). In some embodiments, a user can enter the desired endpoints of the DUV spectrum to be measured, and optionally also the increment (i.e., step) via the keyboard, touchpad, or other user input device 68 of the computer or other controller 64.

In an operation 114, the motorized assembly 80, 82 (or 80ₐₗₜ, 82ₐₗₜ) is operated to place the incident DUV light from the DUV light source 76 at a next location on the EUV pellicle supported by the pellicle stage 72, and process flow returns to the operation 112 via diagrammatic arrow A1 shown in FIG. 5 to acquire the DUV spectrum for this next location. The operations 112 and 114 thereby iterate to scan the DUV light emitted onto the EUV pellicle by the DUV light source 76 over the two-dimensional surface of the EUV pellicle. During this iterative process, the DUV spectrum acquired by each execution of the operation 112 is collected at an operation 116 (as indicated in FIG. 5 by diagrammatic arrow A2) to collect the DUV reflectivity map for the EUV pellicle supported by the pellicle stage 72. The two-dimensional DUV reflectivity map can be suitably stored, for example, as a three-dimensional array (or similar data structure) with two dimensions being the spatial location (set by the operation 110 for the starting location and by the operation 114 for each next location) and the third dimension corresponding to the wavelength (or, equivalently, photon energy) of the reflectivity values over the DUV spectrum acquired at that location.

Although not shown in FIG. 5, in some embodiments the two-dimensional DUV reflectivity map acquired by the operation 58 is repeated at two or more different angles-of-incidence set by the rotation motor 90 (see FIG. 2). For example, if a DUV reflectivity map is collected at each of four different angles of incidence then the output of the operation 58 may be four two-dimensional DUV reflectivity maps, or equivalently a four-dimensional data array (or similar data structure) including two spatial dimensions, a wavelength dimension, and an angle-of-incidence dimension.

The two-dimensional DUV reflectivity map acquired by the operation 58 can be variously utilized. In an operation 120 shown in FIG. 5, a representation of the two-dimensional DUV reflectivity map is displayed (e.g., on the illustrative display 66 of the computer or other controller 64). For example, the measured DUV reflectivity values at the locations on the EUV pellicle 34 can be color coded to produce the representation as a heat map, e.g. with a “hot” color such as red representing highest DUV reflectivity values (optionally integrated over the spectrum for each location) and a “cool” color such as blue representing lowest DUV reflectivity values, and intermediate colors (green, yellow, orange, et cetera) representing intermediate reflectivity values. This is merely one nonlimiting illustrative example of a suitable representation.

Additionally or alternatively, the two-dimensional DUV reflectivity map acquired by the operation 58 can be analyzed by the operation 60 (diagrammatically shown in each of FIGS. 1 and 5) to determine whether the EUV pellicle is usable for EUV lithography (e.g., without a dynamic gas lock DUV light-reflective membrane) by analyzing the two-dimensional DUV reflectivity map. In some examples, the usability of the EUV pellicle 34 is determined based on a reflectivity metric derived from the two-dimensional DUV reflectivity map, such as: the maximum DUV reflectivity at any location on the two-dimensional DUV reflectivity map (optionally integrated over the DUV spectrum for each location); a total DUV reflectivity integrated over the two-dimensional surface of the EUV pellicle (i.e., summed or integrated over all locations of the two-dimensional scan and over all wavelengths scanned by the spectrophotometer); a combination thereof; or so forth.

In an operation 122, an indication of the determination of whether the EUV pellicle is usable for EUV lithography (e.g., without a dynamic gas lock DUV light-reflective membrane) is output (e.g., on the illustrative display 66 of the computer or other controller 64). The indication may be a simple indication of “Pass” or “Fail” where “Pass” indicates the EUV pellicle is usable for the EUV lithography while “Fail” indicates the EUV pellicle is not usable for the EUV lithography. Alternatively, the indication can include more (or alternative) information, such as displaying the value of the reflectivity metric determined from the two-dimensional DUV reflectivity map.

It is also noted that the operation 120 and the operations 60, 122 are not mutually exclusive, e.g., the output could include both display of a representation of the DUV reflectivity map per operation 120 and display of an indication of the determination of whether the EUV pellicle is usable for EUV lithography per operations 60, 122.

In the following, some further embodiments are described.

In a nonlimiting illustrative embodiment, a pellicle DUV reflectivity mapping method includes: acquiring a two-dimensional DUV reflectivity map of an EUV pellicle using a DUV reflectance measurement assembly including: a DUV light source arranged to emit DUV light onto the EUV pellicle to generate reflected DUV light that is reflected by the EUV pellicle, and a DUV spectrophotometer arranged to measure intensity of the reflected DUV light as a function of wavelength or photon energy; and displaying a representation of the two-dimensional DUV reflectivity map.

In a nonlimiting illustrative embodiment, a pellicle DUV reflectivity mapping apparatus includes: a base; a pellicle stage configured to support an associated EUV pellicle; a DUV reflectance measurement assembly including (i) a DUV light source arranged to emit DUV light onto the associated EUV pellicle supported by the pellicle stage to generate reflected DUV light that is reflected by the EUV pellicle, and (ii) a DUV spectrophotometer arranged to measure intensity of the reflected DUV light as a function of wavelength or photon energy; and a motorized assembly secured to the base and configured to scan the DUV light over the associated EUV pellicle in two mutually orthogonal directions by translating the pellicle stage and/or the DUV reflectance measurement assembly respective to the base.

In a nonlimiting illustrative embodiment, a photolithography exposure method includes: acquiring a two-dimensional DUV reflectivity map of an EUV pellicle; determining DUV reflectivity of the EUV pellicle is less than a maximum DUV reflectivity threshold by analyzing the two-dimensional DUV reflectivity map; and, in response to the determination that the DUV reflectivity of the EUV pellicle is less than the maximum DUV reflectivity threshold, mounting the EUV pellicle on an EUV photolithography mask to form an EUV mask assembly and performing EUV photolithography using the EUV mask assembly to form a latent image of a pattern of EUV reflective and absorbing regions of the photomask on and/or in an EUV light-sensitive photoresist layer disposed on a surface of a semiconductor wafer.

In a nonlimiting illustrative embodiment, a two-dimensional DUV reflectivity map of an EUV pellicle is acquired using a DUV reflectance measurement assembly having a DUV light source and a DUV spectrophotometer. A representation of the two-dimensional DUV reflectivity map may be displayed. Additionally or alternatively, it may be determined whether the EUV pellicle is usable for EUV lithography without a dynamic gas lock DUV light-reflective membrane by analyzing the two-dimensional DUV reflectivity map, and outputting an indication of the determination. In response to a determination that the EUV pellicle is usable, the EUV pellicle may be mounted on an EUV photolithography mask to form an EUV mask assembly and EUV photolithography performed using the EUV mask assembly to form a latent image of a pattern of EUV reflective and absorbing regions of the photomask on and/or in an EUV light-sensitive photoresist layer disposed on a surface of a semiconductor wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pellicle deep ultraviolet (DUV) reflectivity mapping method comprising:
acquiring a two-dimensional DUV reflectivity map of an extreme ultraviolet (EUV) pellicle using a DUV reflectance measurement assembly including: a DUV light source arranged to emit DUV light onto the EUV pellicle to generate reflected DUV light that is reflected by the EUV pellicle, and a DUV spectrophotometer arranged to measure intensity of the reflected DUV light as a function of wavelength or photon energy; and
displaying a representation of the two-dimensional DUV reflectivity map.

2. The pellicle DUV reflectivity mapping method of claim 1, wherein the two-dimensional DUV reflectivity map of the EUV pellicle is acquired by scanning the DUV light emitted onto the EUV pellicle over a two-dimensional surface of the EUV pellicle using a combination of moving the EUV pellicle in a first direction respective to the DUV reflectance measurement assembly and moving the EUV pellicle in a second direction respective to the DUV reflectance measurement assembly, wherein the first direction and the second direction are mutually orthogonal.

3. The pellicle DUV reflectivity mapping method of claim 2, wherein the DUV reflectance measurement assembly is at a fixed position respective to a base, and wherein:
the moving of the EUV pellicle in the first direction respective to the DUV reflectance measurement assembly is performed using a first mechanism that is secured to the base; and
the moving of the EUV pellicle in the second direction respective to the DUV reflectance measurement assembly is performed using a second mechanism that is secured to the first mechanism.

4. The pellicle DUV reflectivity mapping method of claim 1, wherein the two-dimensional DUV reflectivity map of the EUV pellicle is acquired by scanning the EUV light emitted onto the EUV pellicle over a two-dimensional surface of the EUV pellicle using a combination of:
moving the DUV reflectance measurement assembly respective to the EUV pellicle in a first direction; and
moving the EUV pellicle in a second direction respective to the DUV reflectance measurement assembly;
wherein the first direction and the second direction are mutually orthogonal.

5. The pellicle DUV reflectivity mapping method of claim 4, wherein:
the moving of the DUV reflectance measurement assembly respective to the EUV pellicle in the first direction is performed using a first linear translation mechanism that is secured to a base; and
the moving of the EUV pellicle in the second direction respective to the DUV reflectance measurement assembly is performed using a second linear translation mechanism that is secured to the base.

6. The pellicle DUV reflectivity mapping method of claim 1, further comprising:
adjusting the DUV reflectance measurement assembly to select an angle of incidence at which the DUV light source emits the DUV light onto the EUV pellicle and an angle of reflectance at which the DUV spectrophotometer measures the intensity of the reflected DUV light.

7. The pellicle DUV reflectivity mapping method of claim 1, further comprising:
operating a photomultiplier tube of the DUV light source to emit the DUV light onto the EUV pellicle.

8. The pellicle DUV reflectivity mapping method of claim 1, wherein the DUV spectrophotometer measures the intensity of the reflected DUV light as a function of wavelength or photon energy over a spectral range of at least 190 nm to 250 nm.

9. The pellicle DUV reflectivity mapping method of claim 1, wherein the displayed representation of the two-dimensional DUV reflectivity map is a heat map.

10. The pellicle DUV reflectivity mapping method of claim 1, further comprising:
determining whether the EUV pellicle is usable for EUV lithography without a dynamic gas lock DUV light-reflective membrane by analyzing the two-dimensional DUV reflectivity map; and
outputting an indication of the determination of whether the EUV pellicle is usable for EUV lithography without a dynamic gas lock DUV light-reflective membrane.

11. The pellicle DUV reflectivity mapping method of claim 10, wherein the determining of whether the EUV pellicle is usable includes:
determining the EUV pellicle is usable if a DUV reflectivity metric derived from the two-dimensional DUV reflectivity map is at or below a maximum threshold.

12. A pellicle deep ultraviolet (DUV) reflectivity mapping apparatus comprising:
a base;
a pellicle stage configured to support an associated extreme ultraviolet (EUV) pellicle;
a DUV reflectance measurement assembly including (i) a DUV light source arranged to emit DUV light onto the associated EUV pellicle supported by the pellicle stage to generate reflected DUV light that is reflected by the EUV pellicle, and (ii) a DUV spectrophotometer arranged to measure intensity of the reflected DUV light as a function of wavelength or photon energy; and
a motorized assembly secured to the base and configured to scan the DUV light over the associated EUV pellicle in two mutually orthogonal directions by moving the pellicle stage and/or the DUV reflectance measurement assembly respective to the base.

13. The pellicle DUV reflectivity mapping apparatus of claim 12, wherein the DUV reflectance measurement assembly is fixed respective to the base, and the motorized assembly includes:
a first mechanism secured to the base and configured to move the pellicle stage respective to the base in a first direction; and
a second mechanism secured to the first mechanism and configured to move the pellicle stage respective to the base in a second direction that is orthogonal to the first direction.

14. The pellicle DUV reflectivity mapping apparatus of claim 12, wherein the motorized assembly includes:
a first mechanism secured to the base and configured to move the DUV reflectance measurement assembly respective to the base in a first direction; and
a second mechanism secured to the base and configured to move the pellicle stage respective to the base in a second direction that is orthogonal to the first direction.

15. The pellicle DUV reflectivity mapping apparatus of claim 12, wherein the DUV reflectance measurement assembly further includes a rotation motor configured to adjust an angle of incidence of the DUV light emitted by the DUV light source onto the associated EUV pellicle supported by the pellicle stage.

16. The pellicle DUV reflectivity mapping apparatus of claim 12, further comprising:
an electronic controller including a display, the electronic controller configured to control the DUV reflectivity mapping apparatus to acquire a two-dimensional DUV reflectivity map of the associated EUV pellicle supported by the pellicle stage and to display a representation of the two-dimensional DUV reflectivity map on the display.

17. The pellicle DUV reflectivity mapping apparatus of claim 12, further comprising:
an electronic controller including a display, the electronic controller configured to:
control the DUV reflectivity mapping apparatus to acquire a two-dimensional DUV reflectivity map of the associated EUV pellicle supported by the pellicle stage, and
determine whether the associated EUV pellicle is usable for EUV lithography without a dynamic gas lock DUV light-reflective membrane by analyzing the two-dimensional DUV reflectivity map, and
output, on the display, an indication of the determination of whether the associated EUV pellicle is usable for EUV lithography without a dynamic gas lock DUV light-reflective membrane.

18. A photolithography exposure method comprising:
acquiring a two-dimensional deep ultraviolet (DUV) reflectivity map of an extreme ultraviolet (EUV) pellicle;
determining DUV reflectivity of the EUV pellicle is less than a maximum DUV reflectivity threshold by analyzing the two-dimensional DUV reflectivity map; and
in response to the determination that the DUV reflectivity of the EUV pellicle is less than the maximum DUV reflectivity threshold, performing EUV photolithography using an EUV mask assembly comprising an EUV mask and the EUV pellicle mounted on the EUV mask to form a latent image of a pattern of EUV reflective and absorbing regions of the photomask on and/or in an EUV light-sensitive photoresist layer disposed on a surface of a semiconductor wafer.

19. The EUV photolithography method of claim 18, wherein the EUV light-sensitive photoresist layer is also DUV light-sensitive.

20. The EUV photolithography method of claim 18, wherein the EUV photolithography is performed without using a dynamic gas lock DUV light-reflective membrane.
